(19) United States
(12) Patent Application Publication
(10) Pub. No.: US 2024/0063023 A1
(43) Pub. Date: Feb. 22, 2024

(54) PATTERNING PROCESS

(71) Applicant: United Microelectronics Corp., Hsinchu (TW)

(72) Inventors: Teng Yao Chang, Tainan City (TW); Chih-Hsien Tang, Taipei City (TW)

(73) Assignee: United Microelectronics Corp., Hsinchu (TW)

(21) Appl. No.: 17/947,186

(22) Filed: Sep. 19, 2022

(30) Foreign Application Priority Data
Aug. 18, 2022 (TW) 111131062

(51) Int. Cl. H01L 21/308; H01L 21/3105; G03F 7/00

(52) U.S. Cl. CPC H01L 21/3086; H01L 21/31053; G03F 7/0002

(57) ABSTRACT

A patterning process is provided. The patterning process comprises the following steps. A material layer is formed on a substrate. An imprinting process is performed on the material layer using an imprint stamp to form a patterned material layer having a plurality of pattern portions. A hard mask layer is formed between adjacent pattern portions. An etching process is performed using the hard mask layer as an etching mask to remove the pattern portions and a part of the substrate. The hard mask layer is removed.

### CROSS-REFERENCE TO RELATED APPLICATION

This application claims the priority benefit of Taiwan application serial no. 111131062, filed on Aug. 18, 2022. The entirety of the above-mentioned patent application is hereby incorporated by reference herein and made a part of this specification.

### BACKGROUND

### Technical Field

The present invention relates to a semiconductor process, and particularly to a patterning process.

### Description of Related Art

With the rapid development of the integrated circuit industry, the dimension of the circuit device needs to be reduced under the condition that the circuit integration is required to be higher and higher. Therefore, after a patterning process, there is a high requirement for the pattern accuracy of a formed device.

In the patterning process that generally adopts an imprinting method, after imprinting the material layer with an imprint stamp, undesired material is likely to remain in the regions between the imprinted patterns. Therefore, an etching process is usually performed to remove residual material. However, during the etching process, in addition to removing the residual material, a part of the imprinted pattern is also removed, thus resulting in reduced pattern accuracy. In particular, critical dimensions (CD) of the devices may be not uniform. As a result, the electrical properties of the formed semiconductor apparatus may be greatly affected.

### SUMMARY

The present invention provides a patterning process that may precisely transfer a desired pattern to a substrate to be patterned.

The patterning process of the present invention includes the following steps. A material layer is formed on a substrate. An imprinting process is performed on the material layer using an imprint stamp to form a patterned material layer having a plurality of pattern portions. A hard mask layer is formed between adjacent pattern portions. An etching process is performed using the hard mask layer as an etching mask to remove the pattern portions and a part of the substrate. The hard mask layer is removed.

In an embodiment of the patterning process of the present invention, the patterned material layer further includes residual portions located between adjacent pattern portions.

In an embodiment of the patterning process of the present invention, the residual portions are removed when the hardmask layer is removed.

In an embodiment of the patterning process of the present invention, the hardmask layer includes a silicon oxide layer, a silicon nitride layer or a combination thereof.

In an embodiment of the patterning process of the present invention, a method for forming the hardmask layer includes the following steps. A hardmask material layer is formed to cover the patterned material layer, wherein the hardmask material layer fills regions between adjacent pattern portions of the patterned material layer. The hardmask material layer on the patterned material layer is removed.

In an embodiment of the patterning process of the present invention, a method for removing the hardmask material layer on the patterned material layer includes performing a chemical mechanical polishing (CMP) process or an etching-back process.

The patterning process of the present invention includes the following steps. A first material layer is formed on an imprint stamp substrate. A first imprinting process is performed on the first material layer using an imprint mold to form a first patterned material layer having a plurality of first pattern portions. A first hardmask layer is formed between adjacent first pattern portions. A first etching process is performed using the first hardmask layer as an etching mask to remove the first pattern portions and a part of the imprint stamp substrate. The first hardmask layer is removed to form an imprint stamp. A second material layer is formed on a substrate. A second imprinting process is performed on the second material layer using the imprint stamp to form a second patterned material layer having a plurality of second pattern portions. An etching process is performed using the second patterned material layer as an etching mask to remove a portion of the substrate. The second patterned material layer is removed.

In an embodiment of the patterning process of the present invention, the first patterned material layer further includes first residual portions located between adjacent first pattern portions.

In an embodiment of the patterning process of the present invention, the first residual portions are removed when the first hardmask layer is removed.

In an embodiment of the patterning process of the present invention, the first hardmask layer includes a silicon oxide layer, a silicon nitride layer or a combination thereof.

In an embodiment of the patterning process of the present invention, a method for forming the first hardmask layer includes the following steps. A hardmask material layer is formed to cover the first patterned material layer, wherein the hardmask material layer fills regions between adjacent first pattern portions of the first patterned material layer. The hardmask material layer is removed on the first patterned material layer.

In an embodiment of the patterning process of the present invention, a method for removing the hardmask material layer on the first patterned material layer includes performing a chemical mechanical polishing process or an etching-back process.

In an embodiment of the patterning process of the present invention, further includes the following steps. A second hardmask layer is formed between adjacent second pattern portions after forming the second patterned material layer. A second etching process is performed using the second hardmask layer as an etching mask to remove the second pattern portions and a part of the substrate. The second hardmask layer is removed.

In an embodiment of the patterning process of the present invention, the second patterned material layer further includes second residual portions located between adjacent second pattern portions.

In an embodiment of the patterning process of the present invention, the second residual portions are removed when the second hardmask layer is removed.

In an embodiment of the patterning process of the present invention, he second hardmask layer includes a silicon oxide layer, a silicon nitride layer or a combination thereof.

In an embodiment of the patterning process of the present invention, a method for forming the second hardmask layer includes the following steps. A hardmask material layer is formed to cover the second patterned material layer, wherein the hardmask material layer fills regions between adjacent second pattern portions of the second patterned material layer. The hardmask material layer is removed on the second patterned material layer.

In an embodiment of the patterning process of the present invention, a method for removing the hardmask material layer on the second patterned material layer includes performing a chemical mechanical polishing process or an etching-back process.

Based on the above, in the present invention, after the imprinting process is performed on the material layer on the substrate, a hardmask layer is formed between adjacent pattern portions. By performing the etching process using the hardmask layer as the etching mask, the pattern at the substrate may be precisely formed. In addition, the residual part of the material layer on the substrate may be removed when the hardmask layer is removed, so there is no need to perform an additional etching process to remove the residual part, thereby ensuring the dimensions and profiles of the patterns formed at the substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A to 1F are schematic cross-sectional views of the patterning process of the first embodiment of the present invention.

FIGS. 2A to 2G are schematic cross-sectional views of the patterning process of the second embodiment of the present invention.

FIGS. 3A to 3D are schematic cross-sectional views of the patterning process of the third embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

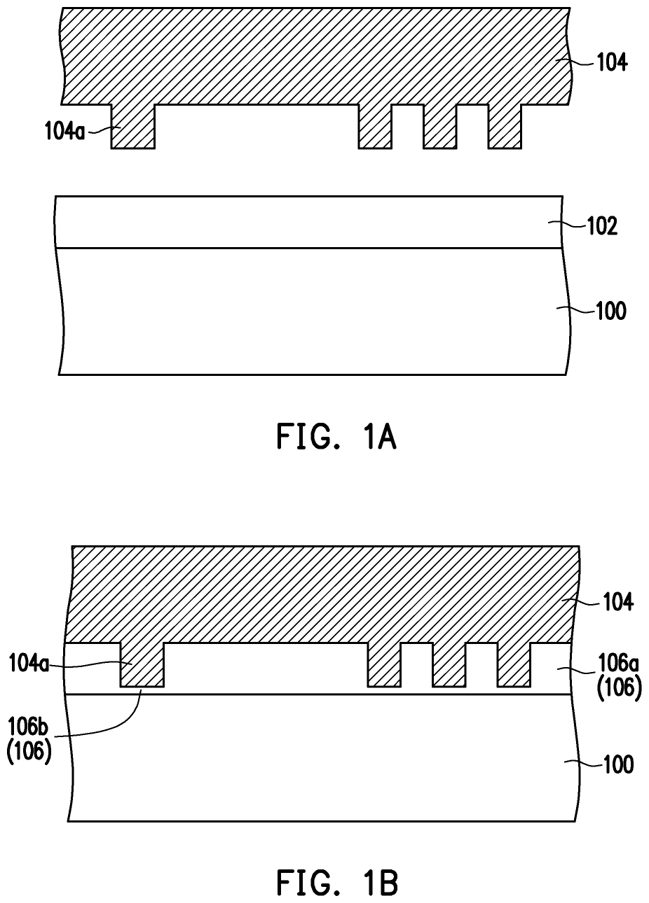

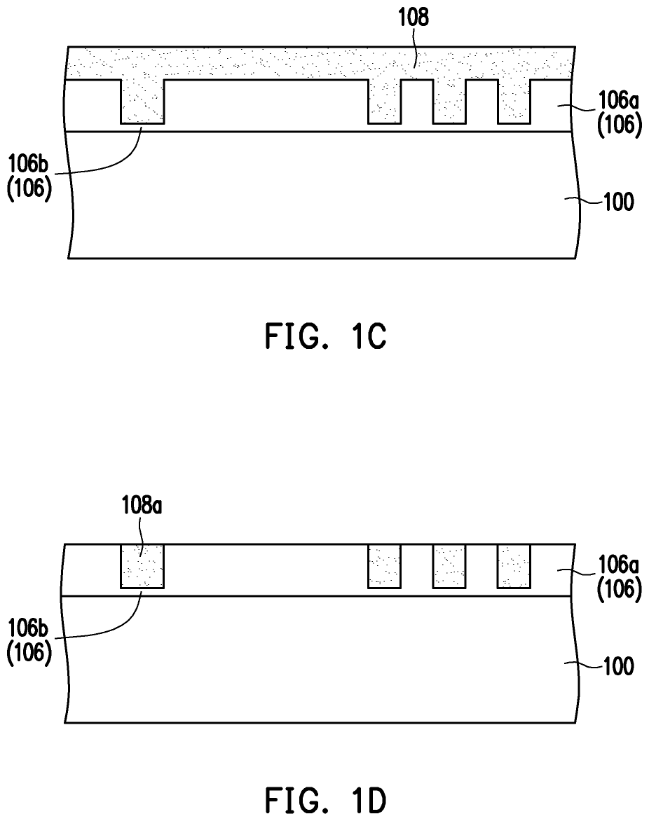

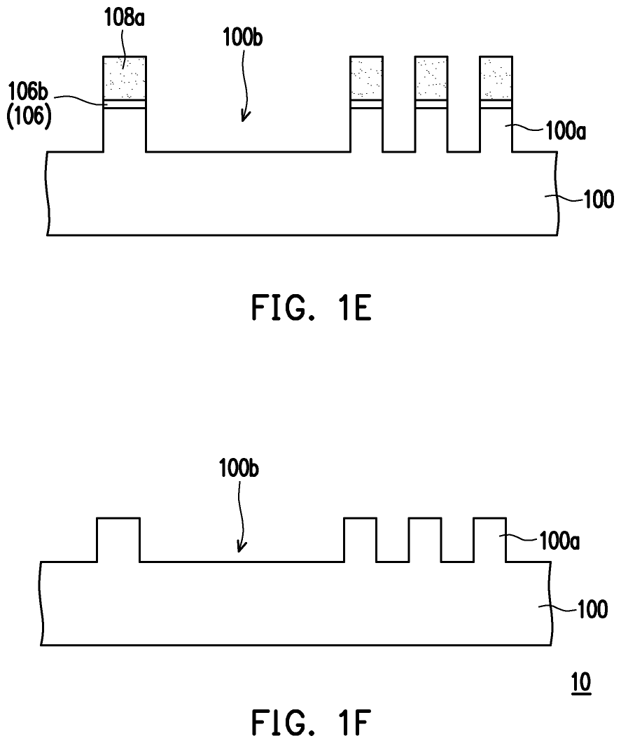

FIGS. 1A to 1F are schematic cross-sectional views of the patterning process of the first embodiment of the present invention.

Referring to FIG. 1A, a material layer 102 is formed on a substrate 100. In the present embodiment, the substrate 100 may be any substrate to be patterned in the semiconductor process. For example, the substrate 100 may be a silicon substrate to be formed with protrusion pattern, or a silicon substrate or a dielectric substrate to be formed with trenches, which is not limited in the present invention. In addition, the material layer 102 is a layer to be subjected to an imprinting process. In the present embodiment, the material layer 102 may be a dielectric layer, but the present invention is not limited thereto.

In addition, an imprint stamp 104 is provided. The imprint stamp 104 is used to perform the imprinting process on the material layer 102. In the present embodiment, the imprint stamp 104 has protrusion portions 104a, and the pattern of the protrusion portions 104a may be corresponded to pattern portions to be formed at the substrate 100. In an embodiment, the imprint stamp 104 may be formed by performing an imprinting process on an imprint stamp substrate using an imprint mold and then performing an etching process, and such technical means are well known to a person skilled in the art, and will not be described herein.

Referring to FIG. 1B, an imprinting process is performed on the material layer 102 using the imprint stamp 104 to form a patterned material layer 106 having a plurality of pattern portions 106a. In detail, the imprint stamp 104 is pressed to the material layer 102 with the protrusion portions 104a facing the material layer 102. At this time, the pattern portions 106a of the patterned material layer 106 formed are corresponded to regions between the protrusion portions 104a of the imprint stamp 104. In addition, during the imprinting process, there may be residual portions 106b of the material layer 102 between the protrusion portions 104a of the imprint stamp 104 and the substrate 100. In other words, after the imprinting process is performed, the formed patterned material layer 106 includes the pattern portions 106a corresponding to the regions between the protrusion portions 104a of the imprint stamp 104 and the residual portions 106b between the protrusion portions 104a of the imprint stamp 104 and the substrate 100.

Referring to FIG. 1C, the imprint stamp 104 is removed. Next, a hardmask material layer 108 is formed on the substrate 100. The hardmask material layer 108 covers the patterned material layer 106 and fills regions between adjacent pattern portions 106a of the patterned material layer 106. In the present embodiment, the hardmask material layer 108 may be a silicon oxide layer, a silicon nitride layer or a combination thereof, but the present invention is not limited thereto.

Referring to FIG. 1D, the hardmask material layer 108 on the patterned material layer 106 is removed to form a hardmask layer 108a between adjacent pattern portions 106a. In the present embodiment, a method for removing the hardmask material layer 108 on the patterned material layer 106 is, for example, to perform a chemical mechanical polishing process or an etching-back process to remove a part of the hardmask material layer 108 until top surfaces of the pattern portions 106a of the patterned material layer 106 are exposed. In this way, the hardmask layer 108a is formed between the adjacent pattern portions 106a and on the residual portions 106b of the patterned material layer 106.

Referring to FIG. 1E, an etching process is performed using the hardmask layer 108a as an etching mask to remove the pattern portions 106a and a part of the substrate 100. In the present embodiment, the hardmask layer 108a is used as the etching mask to perform an anisotropic etching process. Since the residual portions 106b of the patterned material layer 106 are located between the hardmask layer 108a and the substrate 100, the etching process only removes the pattern portions 106a of the patterned material layer 106 and the part of the substrate 100 thereunder, and the residual portions 106b may not be removed. In this way, a plurality of protrusion portions 100a and recessed portions 100b between adjacent protrusion portions 100a may be formed at the substrate 100.

Referring to FIG. 1F, the hardmask layer 108a is removed. In the present embodiment, when the hardmask layer 108a is removed, the residual portions 106b are also removed. In this way, the patterning process of the present embodiment is completed, and the patterned substrate 10 of the present embodiment is formed.

In the patterning process of the present embodiment, after the imprinting process is performed on the material layer 102 using the imprint stamp 104, the hardmask layer 108a is formed between the adjacent pattern portions 106a. By performing the etching process using the hardmask layer 108a as the etching mask, the pattern (protrusion portions 100a) at the substrate 100 may be accurately formed. In addition, the residual portions 106b of the patterned material layer 106 may be removed when the hardmask layer 108a is removed, so there is no need to perform an additional etching process to remove the residual portions 106b, thereby ensuring the dimension and profile of the pattern formed at the substrate 100.

In addition, in the present embodiment, the pattern of the imprint stamp 104 is corresponded to the pattern finally formed at the substrate 100, so it may be seen that the pattern of the imprint mold used to form the imprint stamp 104 and the pattern to be transferred to the substrate 100 belong to “reverse tone”.

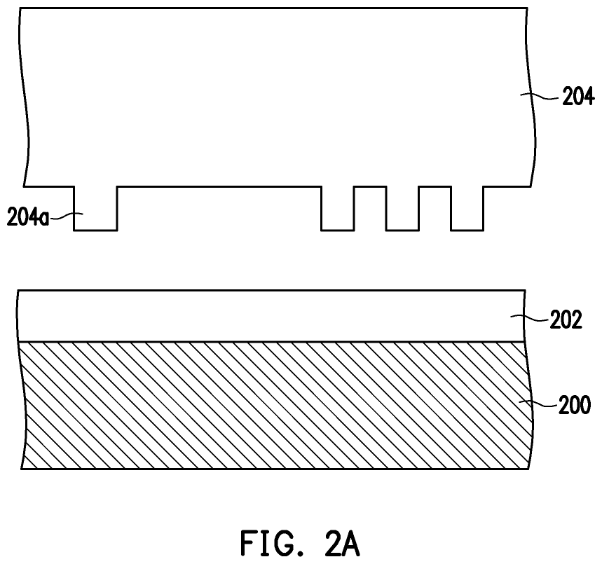

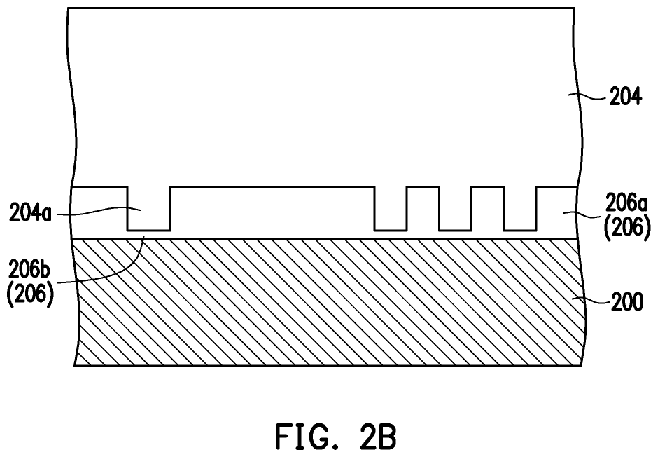

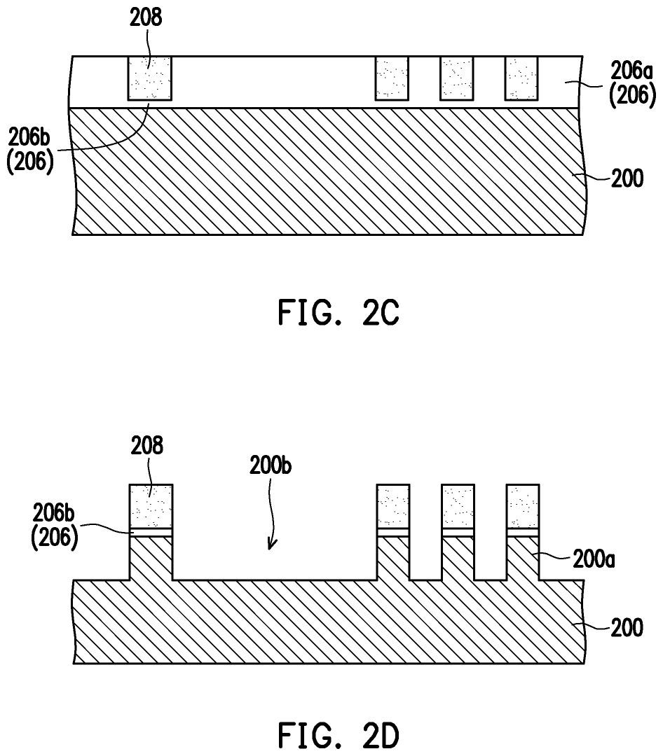

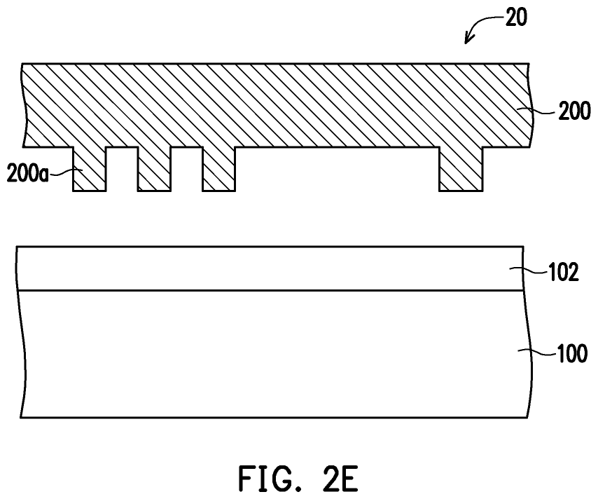

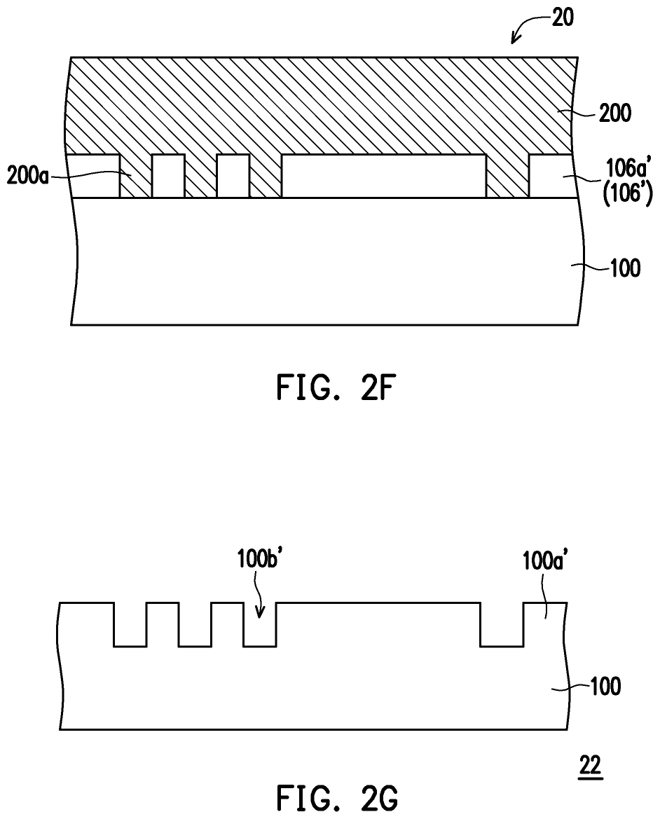

FIGS. 2A to 2G are schematic cross-sectional views of the patterning process of the second embodiment of the present invention. In the present embodiment, the same or similar devices as those in the first embodiment will be denoted by the same or similar reference numbers, and will not be described again.

Referring to FIG. 2A, a first material layer 202 is formed on an imprint stamp substrate 200. In the present embodiment, the first material layer 202 may be a polymer layer, but the present invention is not limited thereto. In addition, an imprint mold 204 is provided. The imprint mold 204 is used to perform an imprinting process on the first material layer 202. In the present embodiment, the imprint mold 204 has protrusion portions 204a, and the pattern of the protrusion portions 204a may be corresponded to pattern portions to be formed at the imprint stamp substrate 200.

Referring to FIG. 2B, an imprinting process is performed on the first material layer 202 using the imprint mold 204 to form a first patterned material layer 206 having a plurality of first pattern portions 206a. In detail, the imprint mold 204 is pressed to the first material layer 202 with the protrusion portions 204a facing the first material layer 202. At this time, the first pattern portions 206a of the first patterned material layer 206 formed are corresponded to regions between the protrusion portions 204a of the imprint mold 204. In addition, during the imprinting process, there may be residual portions 206b of the first material layer 202 between the protrusion portions 204a of the imprint mold 204 and the imprint stamp substrate 200. In other words, after the imprinting process, the formed first patterned material layer 206 includes the first pattern portions 206a corresponding to the regions between the protrusion portions 204a of the imprint mold 204 and the first residual portions 206b between the protrusion portions 204a of the imprint mold 204 and the imprint stamp substrate 200.

Referring to FIG. 2C, the imprint mold 204 is removed. Next, a first hardmask layer 208 may be formed between adjacent first pattern portions 206a of the first patterned material layer 206 in the same manner as described in FIGS. 1C to 1D. In the present embodiment, the first hardmask layer 208 may be a silicon oxide layer, a silicon nitride layer or a combination thereof, but the present invention is not limited thereto. In this way, the first hardmask layer 208 is formed between adjacent first pattern portions 206a and on the first residual portions 206b of the first patterned material layer 206.

Referring to FIG. 2D, an etching process is performed using the first hardmask layer 208 as an etching mask to remove the first pattern portions 206a and a part of the imprint stamp substrate 200. In the present embodiment, an anisotropic etching process is performed using the first hardmask layer 208 as the etching mask. Since the first residual portions 206b of the first patterned material layer 206 are located between the first hardmask layer 208 and the imprint stamp substrate 200, the etching process only removes the first pattern portions 206a of the first patterned material layer 206 and the part of the imprint stamp substrate 200 thereunder, and the first residual portions 206b may not be removed. In this way, a plurality of protrusion portions 200a and recessed portions 200b between adjacent protrusion portions 200a may be formed at the imprint stamp substrate 200.

Referring to FIG. 2E, the first hardmask layer 208 is removed. In the present embodiment, when the first hardmask layer 208 is removed, the first residual portions 206b are also removed. In this way, the imprint stamp 20 of the present embodiment is formed. In the process for forming the imprint stamp 20, after the imprinting process is performed on the first material layer 202 using the imprint mold 204, the first hardmask layer 208 is formed between the adjacent first pattern portions 206a. By performing the etching process using the first hardmask layer 208 as the etching mask, the pattern (protrusion portions 200a) at the imprint stamp substrate 200 may be precisely formed. In addition, the first residual portions 206b of the first patterned material layer 206 may be removed when the first hardmask layer 208 is removed, so there is no need to perform an additional etching process to remove the first residual portions 206, thereby ensuring the dimension and profile of the pattern formed at the imprint stamp substrate 200. As a result, the desired pattern may be accurately transferred to the layer to be patterned by the imprint stamp 20.

In addition, the substrate 100 may be provided as described in FIG. 1A. Then, a second material layer (the material layer 102) is formed on the substrate 100.

Referring to FIG. 2F, an imprinting process is performed on the material layer 102 using the imprint stamp 20. After the imprinting process on the material layer 102 using the imprint stamp 20, a second patterned material layer 106′ having a plurality of second pattern portions 106a′ is formed. In the present embodiment, the protrusion portions 200a of the imprint stamp 20 may be corresponded to regions between adjacent pattern portions to be formed at the substrate 100. Furthermore, in the present embodiment, during the imprinting process, the material layer 102 are not remained between the protrusion portions 200a of the imprint stamp 20 and the substrate 100. That is, in the present embodiment, the protrusion portions 200a of the imprint stamp 20 are in contact with the substrate 100.

Referring to FIG. 2G, the imprint stamp 20 is removed. Next, an etching process is performed using the second patterned material layer 106′ as an etching mask to remove a part of the substrate 100. In the present embodiment, an anisotropic etching process is performed using the second patterned material layer 106′ as the etching mask. After that, the second patterned material layer 106′ is removed to complete the patterning process of the embodiment, and the patterned substrate 22 of the present embodiment is formed. The patterned substrate 22 includes a plurality of protrusion portions 100a′ formed at the substrate 100 and recessed portions 100b′ between adjacent protrusion portions 100a′, wherein the protrusion portions 100a′ are corresponded to the second pattern portions 106a′ of the second patterned material layer 106′.

In the present embodiment, since the pattern of the imprint stamp 20 used has precise dimension and profile, the imprint stamp 20 may be used to transfer the desired pattern to the substrate 100 precisely. In addition, in the present embodiment, the pattern of the imprint mold 204 for forming the imprint stamp 20 as well as the pattern of the imprint stamp 20 and the pattern formed at the substrate 100 belong to “reverse tone”.

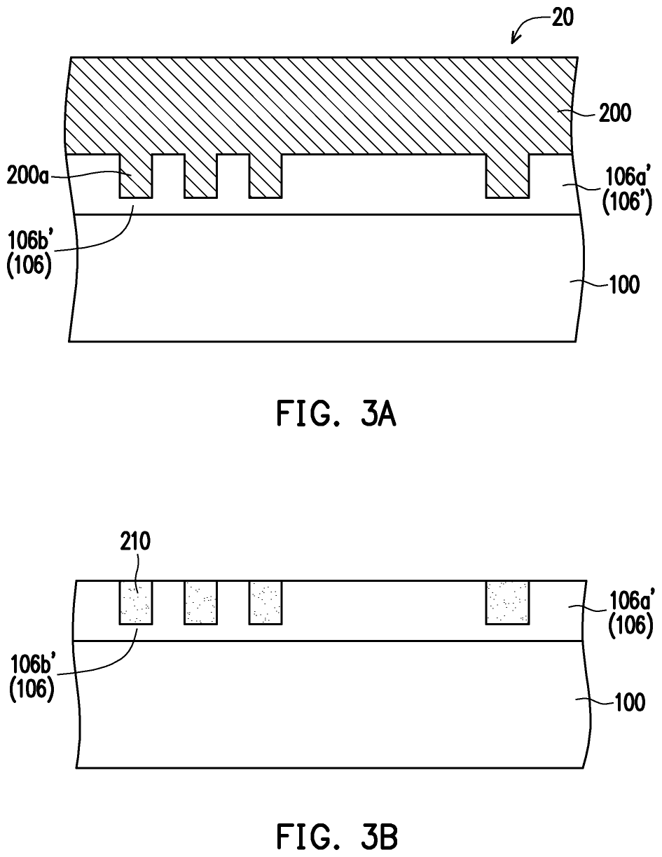

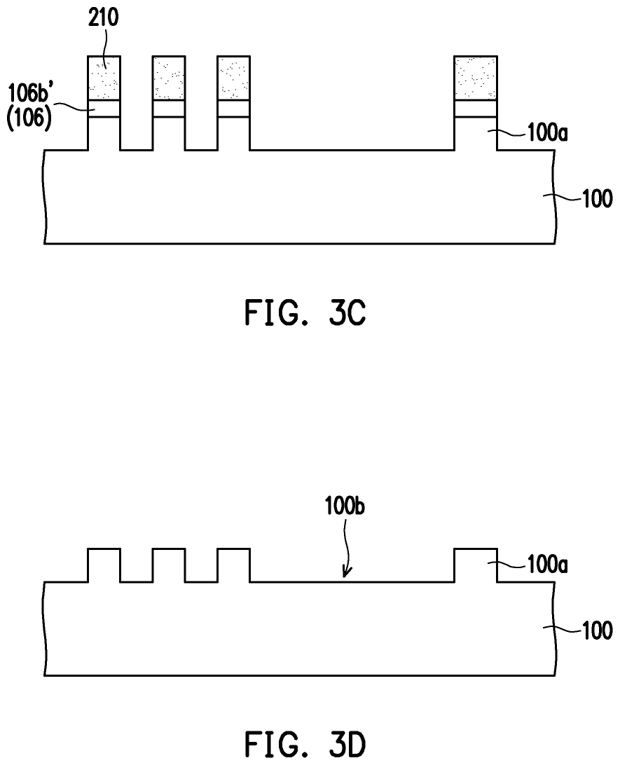

FIGS. 3A to 3D are schematic cross-sectional views of the patterning process of the third embodiment of the present invention. In the present embodiment, the same or similar devices as those in the first embodiment will be denoted by the same or similar reference numbers, and will not be described again.

Referring to FIG. 3A, the steps as described in FIGS. 2A to 2F are performed to form an imprint stamp 20, and the imprint stamp 20 is used to perform an imprinting process on the material layer 102. In the present embodiment, in addition to the second pattern portion 106a′ corresponding to the regions between the protrusion portions 200a of the imprint stamp 20, the second patterned material layer 106′ further includes second residual portions 106b′ located between the protrusion portions 200a of the imprint stamp 20 and the substrate 100.

Referring to FIG. 3B, the imprint stamp 20 is removed. Next, a second hardmask layer 210 may be formed between adjacent second pattern portions 106a′ of the second patterned material layer 106′ in the same manner as described in FIGS. 1C and 1D. In the present embodiment, the second hardmask layer 210 may be a silicon oxide layer, a silicon nitride layer or a combination thereof, but the present invention is not limited thereto. In this way, the second hardmask layer 210 is formed between adjacent second pattern portions 106a′ and on the second residual portions 106b′ of the second patterned material layer 106′.

Referring to FIG. 3C, a second etching process may be performed using the second hardmask layer 210 as an etching mask in the same manner as described in FIG. 1E to remove the second pattern portion 106a′ and a part of the substrate 100. In the present embodiment, an anisotropic etching process is performed using the second hardmask layer 210 as the etching mask. Since the second residual portions 106b′ of the second patterned material layer 106′ are located between the second hardmask layer 210 and the substrate 100, the etching process only removes the second pattern portions 106a′ of the second patterned material layer 106′ and the part of the substrate 100 thereunder, and the second residual portions 106b′ may not be removed. In this way, a plurality of protrusion portions 100a and recessed portions 100b between adjacent protrusion portions 100a may be formed at the substrate 100.

Referring to FIG. 3D, the hardmask layer 210 is removed. In the present embodiment, when the hardmask layer 210 is removed, the second residual portions 106b′ are also removed. In this way, the patterning process of the present embodiment is completed, and the patterned substrate of the present embodiment is formed.

In the patterning process of the present embodiment, after the imprinting process is performed on the material layer 102 using the imprint stamp 20, the second hardmask layer 210 is formed between adjacent second pattern portions 106a′. By performing the etching process using the second hardmask layer 210 as the etching mask, the pattern (the protrusion portions 100a) at the substrate 100 may be precisely formed. Furthermore, the second residual portions 106b′ of the second patterned material layer 106′ may be removed when the hardmask layer 210 is removed. Therefore, in the present embodiment, in addition to using the imprint stamp 20 to accurately transfer the desired pattern to the substrate 100, in the presence of the second residual portions 106b′, there is no need to perform an additional etching process to remove the second residual portions 106b′, thereby ensuring the dimension and profile of the pattern formed at the substrate 100.

In addition, in the present embodiment, the pattern of the imprint mold 204 for forming the imprint stamp 20 and the pattern of the imprint stamp 20 are corresponded to the pattern formed at the substrate 100.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A patterning process, comprising:
forming a material layer on a substrate;
performing an imprinting process on the material layer using an imprint stamp to form a patterned material layer having a plurality of pattern portions;
forming a hardmask layer between adjacent pattern portions;
performing an etching process using the hardmask layer as an etching mask to remove the pattern portions and a part of the substrate; and
removing the hardmask layer.

2. The patterning process of claim 1, wherein the patterned material layer further comprises residual portions located between adjacent pattern portions.

3. The patterning process of claim 2, wherein the residual portions are removed when the hardmask layer is removed.

4. The patterning process of claim 1, wherein the hardmask layer comprises a silicon oxide layer, a silicon nitride layer or a combination thereof.

5. The patterning process of claim 1, wherein a method for forming the hardmask layer comprises:
forming a hardmask material layer to cover the patterned material layer, wherein the hardmask material layer fills regions between adjacent pattern portions of the patterned material layer; and
removing the hardmask material layer on the patterned material layer.

6. The patterning process of claim 5, wherein a method for removing the hardmask material layer on the patterned material layer comprises performing a chemical mechanical polishing process or an etching-back process.

7. A patterning process, comprising:
forming a first material layer on an imprint stamp substrate;
performing a first imprinting process on the first material layer using an imprint mold to form a first patterned material layer having a plurality of first pattern portions;
forming a first hardmask layer between adjacent first pattern portions;
performing a first etching process using the first hardmask layer as an etching mask to remove the first pattern portions and a part of the imprint stamp substrate;
removing the first hardmask layer to form an imprint stamp;
forming a second material layer on a substrate;
performing a second imprinting process on the second material layer using the imprint stamp to form a second patterned material layer having a plurality of second pattern portions;
performing an etching process using the second patterned material layer as an etching mask to remove a portion of the substrate; and
removing the second patterned material layer.

8. The patterning process of claim 7, wherein the first patterned material layer further comprises first residual portions located between adjacent first pattern portions.

9. The patterning process of claim 8, wherein, the first residual portions are removed when the first hardmask layer is removed.

10. The patterning process of claim 7, wherein the first hardmask layer comprises a silicon oxide layer, a silicon nitride layer or a combination thereof.

11. The patterning process of claim 7, wherein a method for forming the first hardmask layer comprises:
forming a hardmask material layer to cover the first patterned material layer, wherein the hardmask material layer fills regions between adjacent first pattern portions of the first patterned material layer; and
removing the hardmask material layer on the first patterned material layer.

12. The patterning process of claim 11, wherein a method for removing the hardmask material layer on the first patterned material layer comprises performing a chemical mechanical polishing process or an etching-back process.

13. The patterning process of claim 7, further comprising:
forming a second hardmask layer between adjacent second pattern portions after forming the second patterned material layer;
performing a second etching process using the second hardmask layer as an etching mask to remove the second pattern portions and a part of the substrate; and
removing the second hardmask layer.

14. The patterning process of claim 13, wherein the second patterned material layer further comprises second residual portions located between adjacent second pattern portions.

15. The patterning process of claim 14, wherein the second residual portions are removed when the second hardmask layer is removed.

16. The patterning process of claim 13, wherein the second hardmask layer comprises a silicon oxide layer, a silicon nitride layer or a combination thereof.

17. The patterning process of claim 13, wherein a method for forming the second hardmask layer comprises:
forming a hardmask material layer to cover the second patterned material layer, wherein the hardmask material layer fills regions between adjacent second pattern portions of the second patterned material layer; and
removing the hardmask material layer on the second patterned material layer.

18. The patterning process of claim 17, wherein a method for removing the hardmask material layer on the second patterned material layer comprises performing a chemical mechanical polishing process or an etching-back process.
